(19) United States
(12) Patent Application Publication
(10) Pub. No.: US 2023/0420397 A1
(43) Pub. Date: Dec. 28, 2023

(54) SEMICONDUCTOR CHIP AND SEMICONDUCTOR PACKAGE INCLUDING THE SAME

(71) Applicant: SAMSUNG ELECTRONICS CO., LTD., SUWON-SI (KR)

(72) Inventors: Hyunsu Hwang, SUWON-SI (KR); Unbyoung Kang, SUWON-SI (KR); Jumyong Park, SUWON-SI (KR); Solji Song, SUWON-SI (KR); Dongjoon Oh, SUWON-SI (KR); Hyunchul Jung, SUWON-SI (KR)

(21) Appl. No.: 18/322,570

(22) Filed: May 23, 2023

(30) Foreign Application Priority Data
Jun. 23, 2022 (KR) 10-2022-0077086

(51) Int. Cl. H01L 23/00; H01L 23/48; H01L 25/065

(52) U.S. Cl. CPC H01L 24/05; H01L 23/48; H01L 25/0657; H01L 24/16; H01L 2224/16145; H01L 2224/05082; H01L 2224/05561; H01L 2224/05567; H01L 2224/05025

(57) ABSTRACT

A includes a semiconductor substrate, a pad insulating layer disposed on the semiconductor substrate, a through electrode structure that partially penetrates the semiconductor substrate but does not penetrate the pad insulating layer, an insulating liner that at least partially surrounds the through electrode structure, an insulating sidewall that penetrates the pad insulating layer, a part of the semiconductor substrate and at least a part of the insulating liner, and includes a pad hole formed therein, and a bonding pad structure disposed on the pad insulating layer and that fills the pad hole, and contacts the through electrode structure

### CROSS-REFERENCE TO RELATED APPLICATION

This application claims priority under 35 U.S.C. § 119 from Korean Patent Application No. 10-2022-0077086, filed on Jun. 23, 2022 in the Korean Intellectual Property Office, the contents of which are herein incorporated by reference in their entirety.

### TECHNICAL FIELD

Embodiments of the inventive concept are directed to a semiconductor chip, a semiconductor package that includes stacked semiconductor chips, and a method of manufacturing the semiconductor chip.

### DISCUSSION OF THE RELATED ART

Miniaturization, multifunctionality, and high performance of electronic products are required, and therefore, high integration and high speed of semiconductor packages are also required. To this end, a semiconductor package that includes a plurality of stacked semiconductor chips has been developed.

### SUMMARY

Embodiments of the inventive concept provide a semiconductor chip, a semiconductor package that includes stacked semiconductor chips, and a method of manufacturing the semiconductor chip.

According to an embodiment of the inventive concept, there is provided a semiconductor chip. The semiconductor chip includes a semiconductor substrate, a pad insulating layer disposed on the semiconductor substrate, a through electrode structure that partially penetrates the semiconductor substrate but does not penetrate the pad insulating layer, an insulating liner that at least partially surrounds the through electrode structure, an insulating sidewall that penetrates the pad insulating layer, a part of the semiconductor substrate and at least a part of the insulating liner, and includes a pad hole formed therein, and a bonding pad structure disposed on the pad insulating layer and that fills the pad hole and contacts the through electrode structure.

According to another embodiment of the inventive concept, there is provided a semiconductor chip. The semiconductor chip includes a semiconductor substrate that includes a first surface and a second surface opposite to each other, a pad insulating layer disposed on the second surface of the semiconductor substrate, a through electrode structure that partially penetrates the semiconductor substrate but does not penetrate the pad insulating layer, where the through electrode structure includes a conductive plug and a plug barrier layer that surrounds the conductive plug, an insulating liner that at least partially surrounds the through electrode structure, an insulating sidewall that penetrates the semiconductor substrate, the pad insulating layer, and the insulating liner and includes a pad hole formed therein, and a bonding pad structure disposed in the pad hole and that partially and vertically overlaps the pad insulating layer and partially penetrates the through electrode structure. The through electrode structure includes a first through electrode structure and a second through electrode structure, and an upper surface of the first through electrode structure is vertically closer to the second surface of the semiconductor substrate than an upper surface of the second through electrode structure.

According to another embodiment of the inventive concept, there is provided a semiconductor package. The semiconductor package includes a first semiconductor chip, and a second semiconductor chip disposed on the first semiconductor chip. The second semiconductor chip includes an upper pad disposed on a lower surface thereof and an upper connection terminal that contacts the upper pad. The first semiconductor chip includes a wiring structure, an interlayer insulating layer that surrounds the wiring structure, a semiconductor substrate disposed on the interlayer insulating layer, a pad insulating layer disposed on the semiconductor substrate, a through electrode structure that partially penetrates the semiconductor substrate but does not penetrate the pad insulating layer, an insulating liner that at least partially surrounds the through electrode structure, an insulating sidewall that penetrates the pad insulating layer, a part of the semiconductor substrate and at least a part of the insulating liner, and includes a pad hole formed therein, and a bonding pad structure that includes a pillar portion that fills the pad hole and a pad portion that covers a part of the pad insulating layer and contacts the through electrode structure. The first semiconductor chip is electrically connected to the second semiconductor chip through a contact between the bonding pad structure and the upper connection terminal.

According to another aspect of the inventive concept, there is provided a method of manufacturing a semiconductor chip. The method of manufacturing the semiconductor chip includes preparing a semiconductor substrate that includes a first surface and a second surface opposite to each other, where the semiconductor substrate is partially penetrated by a through electrode structure and an insulating liner that surrounds the through electrode structure, forming a first insulating layer on the second surface of the semiconductor substrate, disposing a first mask pattern on the first insulating layer and forming an opening hole that at least partially exposes the through electrode structure by at least partially removing the first insulating layer, the semiconductor substrate, and the insulating liner, forming a second insulating layer on the entire second surface of the semiconductor substrate and that at least partially exposes the through electrode structure by at least partially removing the second insulating layer and forming a pad insulating layer, a pad hole, and an insulating sidewall, and forming a bonding pad structure that fills the pad hole.

### BRIEF DESCRIPTION OF THE DRAWINGS

FIG. 1A is a cross-sectional view of a semiconductor chip according to some embodiments.

FIG. 1B is a cross-sectional view of a semiconductor chip according to some embodiments.

FIG. 2A is an enlarged view of a region “I” of FIG. 1A.

FIG. 2B is an enlarged view of a region “I” of a semiconductor chip according to some embodiments.

FIG. 2C is an enlarged view of a region “I” of a semiconductor chip according to some embodiments.

FIG. 3 is an enlarged view of a region “II” in FIG. 2A.

FIG. 4A is an enlarged cross-sectional taken along line A-A′ in FIG. 2A.

FIG. 4B is an enlarged cross-sectional view taken along line B-B′ in FIG. 2A;

FIGS. 5A to 5N are cross-sectional views that illustrate a method of manufacturing a semiconductor chip, according to some embodiments.

FIG. 6A is a cross-sectional view of a semiconductor package according to some embodiments.

FIG. 6B is a cross-sectional view of a semiconductor package according to some embodiments.

### DETAILED DESCRIPTION

Hereinafter, embodiments of the inventive concept are described in detail with reference to the accompanying drawings. The same reference numerals may be used for the same components in the drawings, and redundant descriptions thereof may be omitted.

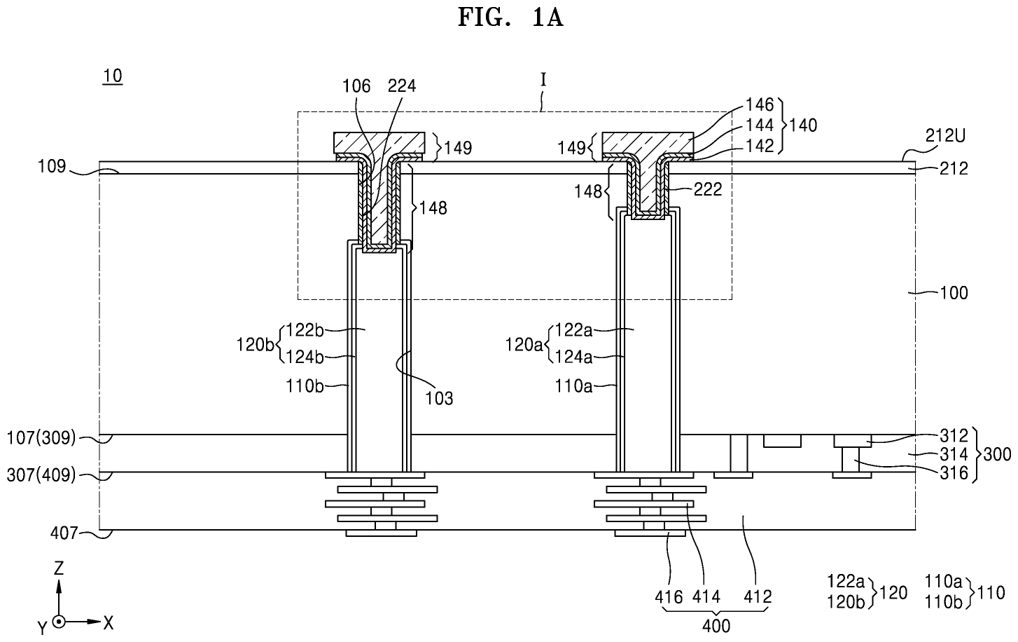

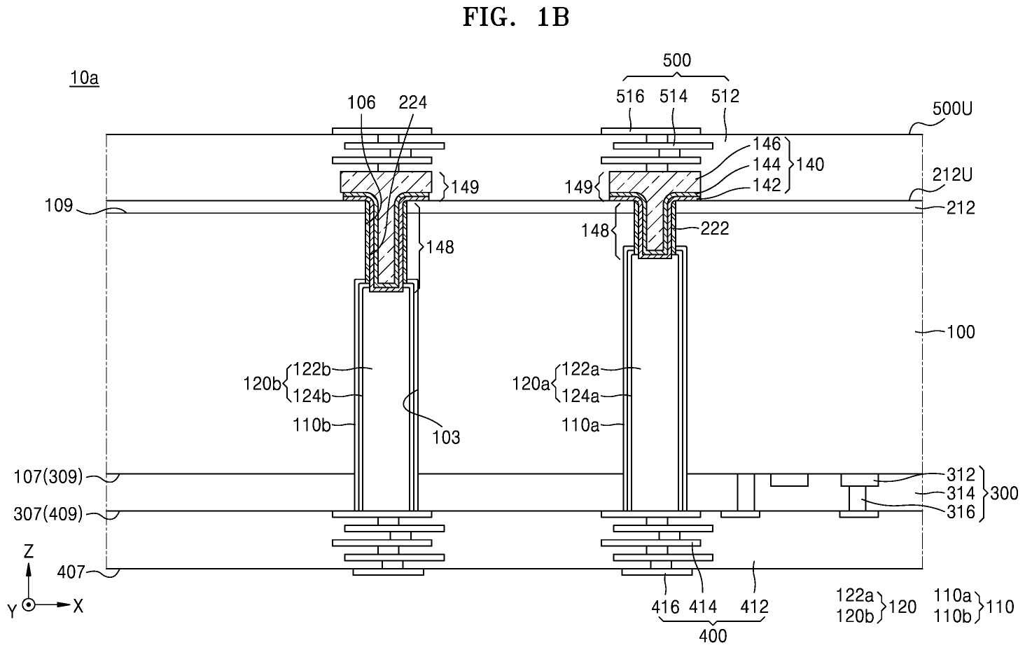

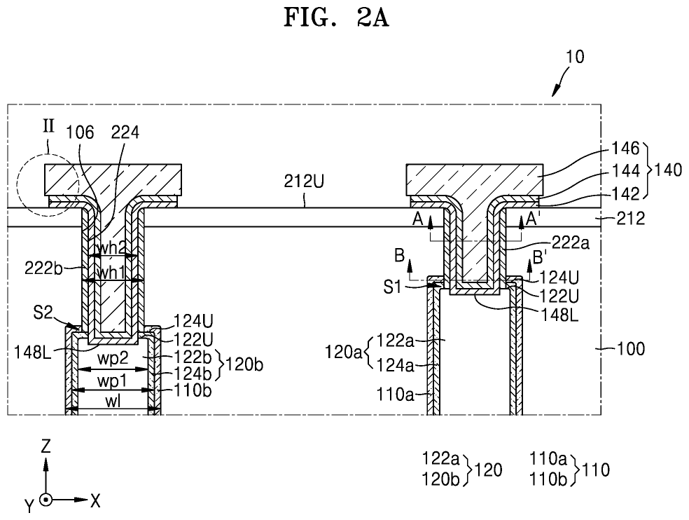

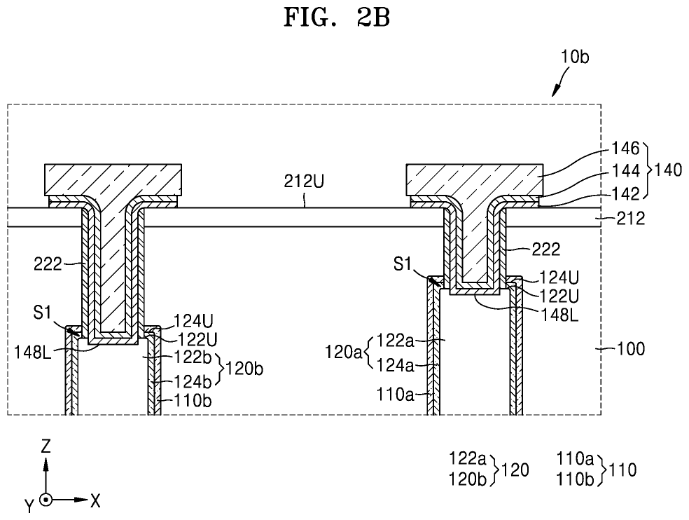

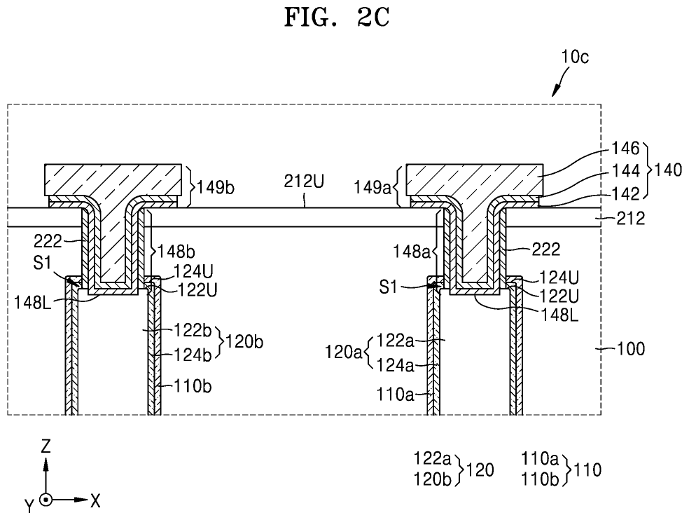

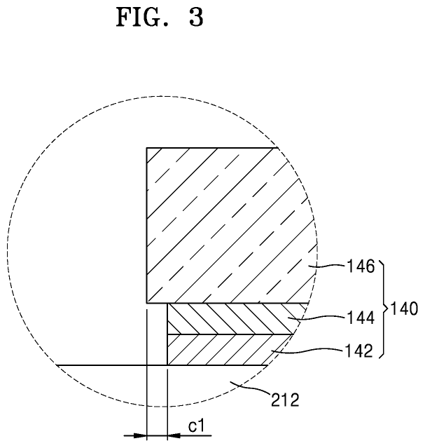

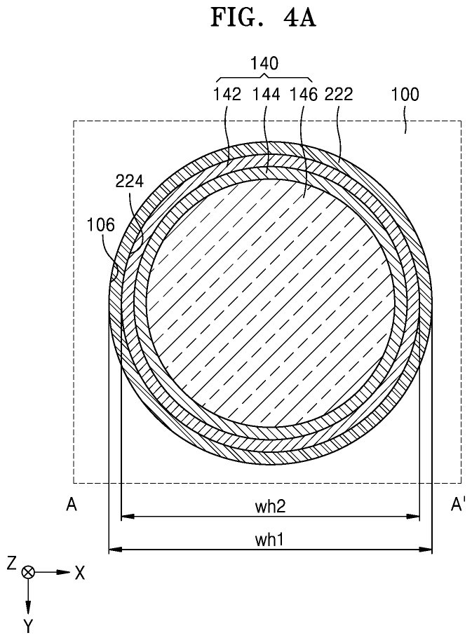

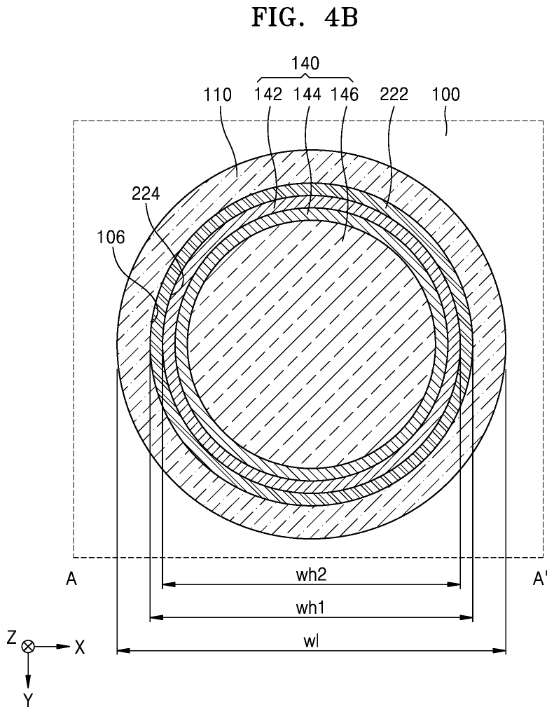

FIG. 1A is a cross-sectional view of a semiconductor chip 10 according to some embodiments. FIG. 2A is an enlarged view of a region “I” of the semiconductor chip 10 according to some embodiments. FIG. 3 is an enlarged view of a region “II” in FIG. 2A. FIG. 4A is an enlarged cross-sectional view of the semiconductor chip 10 according to some embodiments taken along line A-A′ in FIG. 2A. FIG. 4B is an enlarged cross-sectional view of the semiconductor chip 10 according to some embodiments taken along line B-B′ of FIG. 2A.

Referring to FIGS. 1A, 2A, 3, 4A and 4B, the semiconductor chip 10 includes a semiconductor substrate 100, a semiconductor device layer 300, a first wiring structure 400, a pad insulating layer 212, an insulating liner 110, a plurality of through electrode structures 120, and an insulating sidewall 222.

According to some embodiments, the semiconductor substrate 100 includes a first surface 107 and a second surface 109 opposite to each other. For example, the first surface 107 of the semiconductor substrate 100 is a front-side surface of the semiconductor substrate 100, and the second surface 109 of the semiconductor substrate 100 is a back-side surface of the semiconductor substrate 100. For example, the first surface 107 is an active surface of the semiconductor substrate 100, and the second surface 109 is an inactive surface of the semiconductor substrate 100.

Hereinafter, a direction parallel to the first surface 107 of the semiconductor substrate 100 is defined as a horizontal direction, such as an X direction and/or a Y direction, and a direction normal to the first surface 107 of the semiconductor substrate 100 is defined as a vertical direction, such as a Z direction. In addition, a width of an arbitrary member is a length in the horizontal direction, such as the X direction and/or the Y direction, and a vertical height of the arbitrary member is a length in the vertical direction, such as the Z direction

The semiconductor substrate 100 is formed from a semiconductor wafer. For example, the semiconductor substrate 100 includes silicon (Si). For example, the semiconductor substrate 100 includes a semiconductor element, such as germanium (Ge), or a compound semiconductor, such as one of silicon carbide (SiC), gallium arsenide (GaAs), indium arsenide (InAs), or indium phosphide (InP). The semiconductor substrate 100 includes a conductive region, such as a well doped with an impurity or a structure doped with an impurity. In addition, the semiconductor substrate 100 has a shallow trench isolation (STI) structure.

The semiconductor device layer 300 is disposed on the first surface 107 of the semiconductor substrate 100. An upper surface 309 of the semiconductor device layer 300 is substantially the same as the first surface 107 of the semiconductor substrate 100. The semiconductor device layer 300 includes a front end of line (FEOL) structure formed on the first surface 107 of the semiconductor substrate 100. For example, the semiconductor device layer 300 includes a circuit pattern 312 that forms at least one of a transistor, a diode, etc., and an interlayer insulating layer 314 that surrounds the circuit pattern 312. The circuit pattern 312 is electrically connected to a first wiring pattern 414 of the first wiring structure 400 through a contact plug 316.

The contact plug 316 includes doped polysilicon, and includes a metal, such as at least one of aluminum (Al), copper (Cu), nickel (Ni), or an alloy thereof.

The first wiring structure 400 is disposed on a lower surface 307 of the semiconductor device layer 300. The first wiring structure 400 includes a back end of line (BEOL) structure formed below the semiconductor device layer 300. The first wiring structure 400 include a first wiring insulating layer 412 disposed on the lower surface 307 of the semiconductor device layer 300 and a plurality of conductive first wiring patterns 414 provided in the first wiring insulating layer 412. At least some of the plurality of conductive first wiring patterns 414 of the first wiring structure 400 are electrically connected to the through electrode structure 120. In addition, at least some of the plurality of first wiring patterns 414 of the first wiring structure 400 are electrically connected to a transistor, a diode, etc., in the semiconductor device layer 300.

The plurality of first wiring patterns 414 of the first wiring structure 400 include a plurality of wiring lines and a plurality of wiring vias. The plurality of wiring lines and the plurality of wiring vias are covered by the first wiring insulating layer 412. Each of the plurality of wiring lines extends in the horizontal direction, such as the X direction and/or the Y direction, inside the first wiring insulating layer 412. The plurality of wiring lines are positioned at different levels in the vertical direction, such as the Z direction, inside the first wiring insulating layer 412 to form a multilayer wiring structure. The plurality of wiring vias extend in the vertical direction between the plurality of wiring lines at different vertical levels to electrically connect the plurality of wiring lines positioned at different vertical levels.

The first wiring structure 400 further includes a first contact pad 416 exposed on the lower surface 407 of the first wiring structure 400. The first contact pad 416 is electrically connected to another semiconductor chip or wafer.

The plurality of wiring lines and the plurality of wiring vias include a metal, such as one of copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), etc., or an alloy thereof. For example, the first contact pad 416 includes a metal, such as aluminum (Al), copper (Cu), or nickel (Ni), etc., or an alloy thereof.

According to some embodiments, the first wiring insulating layer 412 includes an oxide and/or a nitride. For example, the first wiring insulating layer 412 includes silicon oxide and/or silicon nitride. In some embodiments, the first wiring insulating layer 412 includes an insulating material made of a Photo Imageable Dielectric (PID) material with which a photolithography process may be performed. For example, the first wiring insulating layer 412 includes photosensitive polyimide (PSPI).

According to some embodiments, the pad insulating layer 212 is disposed on the second surface 109 of the semiconductor substrate 100. For example, the pad insulating layer 212 covers the second surface 109 of the semiconductor substrate 100. In some embodiments, the pad insulating layer 212 includes an oxide and/or a nitride. For example, the pad insulating layer 212 includes at least one of SiO, SiN, SiCN, SiCO, or a polymer material. For example, the polymer material is one of benzocyclobutene (BCB), polyimide (PI), polybenzoxazole (PBO), silicone, or epoxy.

According to some embodiments, the through electrode structure 120 partially penetrates the semiconductor substrate 100. For example, the through electrode structure 120 penetrates the first surface 107 of the semiconductor substrate 100, but not the second surface 109 of the semiconductor substrate 100. For example, the through electrode structure 120 is spaced apart in the vertical (Z) direction from the second surface 109 of the semiconductor substrate 100. For example, the semiconductor substrate 100 includes a via hole 103 that extends in the vertical (Z) direction from the first surface 107 and but does not penetrate the second surface 109, and the through electrode structure 120 fill the via hole 103.

For example, the through electrode structure 120 is a via-middle type that extends in the vertical (Z) direction from the lower surface 307 of the semiconductor device layer 300, and penetrates the semiconductor device layer 300. The semiconductor chip 10 according to some embodiments shown in FIG. 1A is a via-middle type.

In some embodiments, the through electrode structure 120 is a via-first type that extends in the vertical (Z) direction from the first surface 107 of the semiconductor substrate 100 toward the second surface 109 of the semiconductor substrate 100. For example, the through electrode structure 120 does not penetrate the semiconductor device layer 300. For example, the semiconductor device layer 300 includes a contact structure that electrically connects the through electrode structure 120 and the first wiring structure 400. In some embodiments, the through electrode structure 120 is a via-last type that extends in the vertical (Z) direction from the lower surface 407 of the first wiring structure 400 toward the second surface 109 of the semiconductor substrate 100. For example, the through electrode structure 120 penetrates the first wiring structure 400 and the semiconductor device layer 300.

According to some embodiments, the through electrode structure 120 includes a conductive plug 122 and a plug barrier layer 124. In some embodiments, the conductive plug 122 has a pillar shape that partially penetrates the semiconductor substrate 100. In some embodiments, the plug barrier layer 124 partially surrounds the conductive plug 122. For example, the plug barrier layer 124 surrounds a side surface of the conductive plug 122 and covers an upper surface 122U of the conductive plug 122.

For example, for a via-middle type, the conductive plug 122 extends in the vertical (Z) direction from the lower surface 307 of the semiconductor device layer 300 and penetrates the semiconductor device layer 300, and partially penetrates the semiconductor substrate 100 to be spaced apart from the second surface 109 of the semiconductor substrate 100. For example, the plug barrier layer 124 surrounds the entire side surface of the conductive plug 122 inside the semiconductor device layer 300 and the semiconductor substrate 100.

In some embodiments, the conductive plug 122 includes at least one of copper (Cu), nickel (Ni), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), or ruthenium (Ru). In some embodiments, the plug barrier layer 124 includes at least one of titanium (Ti), titanium nitride (TiN), tantalum (Ta), tantalum nitride (TaN), tungsten (W), tungsten nitride (WN), ruthenium (Ru) or cobalt (Co). In some embodiments, the conductive plug 122 and the plug barrier layer 124 are formed by a physical vapor deposition (PVD) process or a chemical vapor deposition (CVD) process, and/or a plating process.

In some embodiments, the insulating liner 110 includes an ozone/tetra-ethyl ortho-silicate (O₃/TEOS)-based high aspect ratio process (HARP) oxide formed by a sub-atmospheric CVD process.

According to some embodiments, the insulating liner 110 surrounds the through electrode structure 120. For example, the insulating liner 110 is disposed in the via hole 103, and is disposed between the through electrode structure 120 and the semiconductor substrate 100. For example, the insulating liner 110 entirely surrounds the side surface of the through electrode structure 120 and partially covers the upper surface of the through electrode structure 120. For example, for a via-middle type, the insulating liner 110 extends in the vertical (Z) direction from the lower surface 307 of the semiconductor device layer 300 together with the through electrode structure 120 and surrounds the through electrode structure 120.

According to some embodiments, an insulating sidewall 222 is disposed in an open hole 106. According to some embodiments, the open hole 106 extends in the vertical (Z) direction from the upper surface 212U of the pad insulating layer 212, penetrates the pad insulating layer 212 and the semiconductor substrate 100 between the through electrode structure 120 and the pad insulating layer 212, and at least partially penetrates the insulating liner 110. According to some embodiments, the open hole 106 penetrates the insulating liner 110, and for example, the insulating sidewall 222 contacts the through electrode structure 120. For example, the open hole 106 is limited by the pad insulating layer 212, the semiconductor substrate 100, the insulating liner 110, and the through electrode structure 120.

According to some embodiments, the open hole 106 partially penetrates the through electrode structure 120. For example, the open hole 106 penetrates the plug barrier layer 124, and the insulating sidewall 222 contacts the conductive plug 122. For example, the open hole 106 is limited by the pad insulating layer 212, the semiconductor substrate 100, the insulating liner 110, the plug barrier layer 124, and the conductive plug 122.

According to some embodiments, the insulating sidewall 222 has a hollow cylindrical shape that penetrates through upper and lower surfaces, and the pad hole 224 is limited by an inner circumferential surface of the insulating sidewall 222. According to some embodiments, a bonding pad structure 140 is disposed inside the pad hole 224 and contacts the through electrode structure 120.

According to some embodiments, the insulating sidewall 222 is disposed between the semiconductor substrate 100 and the bonding pad structure 140 and electrically and physically separates the semiconductor substrate 100 and the bonding pad structure 140. Accordingly, an electro-migration phenomenon in which metal atoms of the bonding pad structure 140 move to the semiconductor substrate 100 is prevented, and the electrical reliability of the semiconductor chip 10 is increased.

According to some embodiments, the insulating sidewall 222 penetrates the insulating liner 110. According to some embodiments, a width wh1 of the insulating sidewall 222 in the horizontal (X and/or Y) direction is narrower than a width w1 of the insulating liner 110 in the horizontal direction. For example, the width wh1 of the insulating sidewall 222 in the horizontal direction is the same as a diameter of an outer circumferential surface of the hollow cylindrically-shaped insulating sidewall 222. For example, the width w1 of the insulating liner 110 in the horizontal direction is the same as a diameter of an outer circumferential surface of the hollow cylindrically-shaped insulating liner 110.

According to some embodiments, the insulating sidewall 222 is partially surrounded by the insulating liner 110. For example, a part of the outer circumferential surface of the insulating sidewall 222 that penetrates the insulating liner 110 is surrounded by the insulating liner 110. Accordingly, the structural stability of the bonding pad structure 140 and the through electrode structure 120 is increased. For example, stress is applied in the horizontal direction in a process of forming the semiconductor package 1000, or in a process of mounting the semiconductor chip 10 on an electronic device, as described below. The semiconductor chip 10 according to some embodiments has a structure in which the insulating sidewall 222 is surrounded by the insulating liner 110, thereby preventing the insulating sidewall 222 from being detached from the through electrode structure 120.

In some embodiments, the semiconductor chip 10 has a first combining structure S1 in which the insulating sidewall 222 partially penetrates the through electrode structure 120. For example, the insulating sidewall 222 penetrates the plug barrier layer 124 and contacts the upper surface 122U of the conductive plug 122. In some embodiments, the width wh1 of the insulating sidewall 222 in the horizontal (X and/or Y) direction is narrower than a width wp1 of the plug barrier layer 124 in the horizontal (X and/or Y) direction, and the insulating sidewall 222 is partially surrounded by the plug barrier layer 124. For example, a part of the insulating sidewall 222 that penetrates the plug barrier layer 124 is surrounded by the plug barrier layer 124. For example, in the first combining structure S1, the insulating sidewall 222 is bound by the insulating liner 110, the plug barrier layer 124, the bonding pad structure 140, and the conductive plug 122. For example, the width wp1 of the plug barrier layer 124 in the horizontal direction is the same as a diameter of an outer circumferential surface of the hollow cylindrically-shaped plug barrier layer 124.

In an embodiment, the width wh1 of the insulating sidewall 222 in the horizontal direction may be substantially the same as a width wp2 of the conductive plug 122 in the horizontal direction. In an embodiment, the width wh1 of the insulating sidewall 222 in the horizontal direction may be narrower than the width wp2 of the conductive plug 122 in the horizontal direction. In some embodiments, the semiconductor chip 10 has a second combining structure S2 in which the insulating sidewall 222 does not penetrate the through electrode structure 120. For example, the insulating sidewall 222 contacts an upper surface 124U of the plug barrier layer 124. For example, the insulating sidewall 222 does not penetrate the plug barrier layer 124, and the insulating sidewall 222 does not contact the conductive plug 122. For example, in the second combining structure S2, the insulating sidewall 222 is bound by the insulating liner 110, the bonding pad structure 140, and the plug barrier layer 124.

In some embodiments, insulating sidewall 222 includes an oxide and/or a nitride. For example, the insulating sidewall 222 includes at least one of SiO, SiN, SiCN, SiCO, or a polymer material. For example, the polymer material is one of benzocyclobutene (BCB), polyimide (PI), polybenzoxazole (PBO), silicone, or epoxy.

According to some embodiments, the bonding pad structure 140 includes a pillar portion 148 that fills the pad hole 224 and a pad portion 149 disposed on the pad insulating layer 212. According to some embodiments, the pillar portion 148 and the pad portion 149 are integrally formed, and the pillar portion 148 extends from a lower surface of the pad portion 149 and fills the pad hole 224.

According to some embodiments, the pad hole 224 partially penetrates the through electrode structure 120 and extends into the through electrode structure 120. For example, a width wh2 of the pad hole 224 in the horizontal (X and/or Y) direction is narrower than a width of the through electrode structure 120 in the horizontal direction, that is, the width wp1 of the plug barrier layer 124 in the horizontal direction. According to some embodiments, the pad hole 224 penetrates the plug barrier layer 124 and partially penetrates the conductive plug 122. For example, the width wh2 of the pad hole 224 in the horizontal direction is narrower than the width wp2 of the conductive plug 122 in the horizontal direction.

In some embodiments, when the through electrode structure 120 and the insulating sidewall 222 have the first combining structure S1, the pad hole 224 is limited by the inner circumferential surface of the insulating sidewall 222 and the conductive plug 122.

In some embodiments, when the through electrode structure 120 and the insulating sidewall 222 have the second combining structure S2, the pad hole 224 is limited by the inner circumferential surface of the insulating sidewall 222, the plug barrier layer 124, and the conductive plug 122.

According to some embodiments, the bonding pad structure 140 fills the pad hole 224 and partially penetrates the through electrode structure 120. According to some embodiments, the pillar portion 148 of the bonding pad structure 140 partially extends into the through electrode structure 120. For example, the pillar portion 148 of the bonding pad structure 140 penetrates the plug barrier layer 124 and partially extends into the conductive plug 122. For example, a lower surface 148L of the pillar portion 148 is positioned at a vertical level that is lower than the upper surface 122U of the conductive plug 122.

In some embodiments, the width wh2 of the pad hole 224 in the horizontal direction is substantially the same as the width wp2 of the conductive plug 122 in the horizontal direction. In some embodiments, the width wh2 of the pad hole 224 in the horizontal direction is wider than the width wp2 of the conductive plug 122 in the horizontal direction and narrower than the width wp1 of the plug barrier layer 124 in the horizontal direction. For example, the pillar portion 148 of the bonding pad structure 140 contacts the through electrode structure 120 without substantially penetrating the through electrode structure 120.

According to some embodiments, the bonding pad structure 140 includes a pad barrier layer 142 that partially fills the pad hole 224 and is partially disposed on the pad insulating layer 212, a pad seed layer 144 disposed on the pad barrier layer 142 and that partially fills the pad hole 224, and a conductive pad pattern 146 disposed on the pad seed layer 144 and that partially fills the pad hole 224.

In some embodiments, a horizontal cross-section of the pillar portion 148 of the bonding pad structure 140 has a concentric circle shape. For example, the pad barrier layer 142 that partially fills the pad hole 224 covers the inner circumferential surface of the insulating sidewall 222 and the conductive plug 122, and forms a space in the pad hole 224 limited by the pad barrier layer 142. For example, the pad seed layer 144 has substantially the same shape as the pad barrier layer 142 and is disposed on the pad barrier layer 142, and forms a space in the pad hole 224 limited by the pad seed layer 144. For example, the conductive pad pattern 146 fills the space limited by the pad seed layer 144.

According to some embodiments, a width of the pad portion 149 of the bonding pad structure 140 in the horizontal direction is wider than a width of the pillar portion 148 of the bonding pad structure 140 in the horizontal direction. For example, the width of the pad portion 149 of the bonding pad structure 140 in the horizontal direction is wider than a width of the through electrode structure 120 in the horizontal direction.

According to some embodiments, the outer surface of the pad portion 149 of the bonding pad structure 140 has an under-cut structure. For example, widths of the pad barrier layer 142 and the pad seed layer 144 of the pad portion 149 in the horizontal direction are narrower than a width of the conductive pad pattern 146 of the pad portion 149 in the horizontal direction. For example, the outer surface of the conductive pad pattern 146 protrudes from the outer surface of the pad barrier layer 142 and the pad seed layer 144 by a first distance c1. For example, the pad portion 149 has a shape in which a lower portion of the outer surface of the pad portion 149 is concave inward. Although FIG. 3 shows that each of the pad barrier layer 142 and the pad seed layer 144 has a straight outer cross-section, embodiments are not necessarily limited thereto, and in some embodiments, have a curved shape that is concave inward.

In some embodiments, the pad barrier layer 142 includes at least one of titanium (Ti), titanium nitride (TiN), tantalum (Ta), tantalum nitride (TaN), tungsten (W), tungsten nitride (WN), ruthenium (Ru), or cobalt (Co). The pad seed layer 144 includes at least one of chromium (Cr), tungsten (W), titanium (Ti), copper (Cu), nickel (Ni), aluminum (Al), palladium (Pd), gold (Au), or a combination thereof. In some embodiments, the pad seed layer 144 has a structure in which a Ti layer, a TiW layer, and a Cu layer are stacked. In some embodiments, the conductive pad pattern 146 includes at least one of copper (Cu), nickel (Ni), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), or ruthenium (Ru). In some embodiments, the pad barrier layer 142, the pad seed layer 144, and the conductive pad pattern 146 are formed by a PVD process or a CVD process, and/or a plating process. For example, the conductive pad pattern 146 is formed through an electroplating process by using the pad seed layer 144 as a seed.

According to some embodiments, the through electrode structure 120 includes a first through electrode structure 120a and a second through electrode structure 120b that are spaced apart from the second surface 109 of the semiconductor substrate 100 by different distances. For example, the upper surface of the first through electrode structure 120a is closer to the second surface 109 of the semiconductor substrate 100 than the upper surface of the second through electrode structure 120b.

In some embodiments, the semiconductor chip 10 includes a plurality of through electrode structures 120. The first through electrode structure 120a is one of the plurality of through electrode structures 120 whose upper surface is relatively closer in the vertical direction to the second surface 109 of the semiconductor substrate 100 in the vertical direction, and the second through electrode structure 120b is one of the plurality of through electrode structures 120 whose upper surface is relatively farther in the vertical direction from the second surface 109 of the semiconductor substrate 100.

According to some embodiments, the first through electrode structure 120a and the first insulating sidewall 222a that contacts the first through electrode structure 120a have the first combining structure S1, and the second through electrode structure 120b and the second insulating sidewall 222b that contacts the second through electrode structure 120b have the second combining structure S2.

In some embodiments, a length in the vertical direction of the second insulating sidewall 222b in the vertical (Z) direction is greater than a length of the first insulating sidewall 222a.

In some embodiments, a length in the vertical direction of the pillar portion 148 of the bonding pad structure 140 that contacts the second through electrode structure 120b is greater than a length of the pillar portion 148 of the bonding pad structure 140 contacting the first through electrode structure 120a.

FIG. 1B is a cross-sectional view of a semiconductor chip 10a according to some embodiments. A difference between FIGS. 1A and 1B is whether the semiconductor chip 10a includes a second wiring structure 500.

Referring to FIG. 1B, in an embodiment, the semiconductor chip 10a further includes the second wiring structure 500 formed on the second surface 109 of the semiconductor substrate 100. In some embodiments, the second wiring structure 500 includes a second wiring insulating layer 512 that covers the upper surface 212U of the pad insulating layer 212 and surrounds the pad portion 149 of the bonding pad structure 140. In some embodiments, the second wiring structure 500 includes a second wiring pattern 514 disposed in the second wiring insulating layer 512. For example, a plurality of second wiring patterns 514 are provided, and at least some of the second wiring patterns 514 are electrically connected to the bonding pad structure 140.

The plurality of conductive second wiring patterns 514 of the second wiring structure 500 include a plurality of wiring lines and a plurality of wiring vias. The plurality of wiring lines and the plurality of wiring vias are surrounded by the second wiring insulating layer 512. Each of the plurality of wiring lines extends in a horizontal (X and/or Y) direction inside the second wiring insulating layer 512. The plurality of wiring lines are positioned at different levels in a vertical (Z) direction in the second wiring insulating layer 512 and form a multilayer wiring structure. The plurality of wiring vias extend in the vertical (Z) direction between the plurality of wiring lines at different vertical levels and electrically connect the plurality of wiring lines positioned at different vertical levels.

The second wiring structure 500 further includes a second contact pad 516 exposed on an upper surface 500U of the second wiring structure 500. For example, the second contact pad 516 are electrically connected to another semiconductor chip or wafer disposed on the semiconductor chip 10a. In some embodiments, the plurality of wiring lines and the plurality of wiring vias include a metal, such as one of copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), etc., or an alloy thereof. For example, the second contact pad 516 includes a metal, such as one of aluminum (Al), copper (Cu), nickel (Ni), or an alloy thereof.

According to some embodiments, the second wiring insulating layer 512 includes an oxide and/or a nitride. For example, the second wiring insulating layer 512 includes silicon oxide and/or silicon nitride. According to some embodiments, the second wiring insulating layer 512 includes an insulating material made of a PID material suitable for a photolithography process. For example, the second wiring insulating layer 512 includes PSPI.

FIG. 2B is an enlarged view of a semiconductor chip 10b according to some embodiments. For example, FIG. 2B is an enlarged view of the region “I” in FIG. 1A. A difference between FIGS. 2A and 2B is whether the second through electrode structure 120b and the second insulating sidewall 222b contacting the second through electrode structure 120b have the first combining structure S1.

Referring to FIG. 2B, a combining structure of the second through electrode structure 120b and the second insulating sidewall 222b that contacts the second through electrode structure 120b is substantially the same as a combining structure of the first through electrode structure 120a and the first insulating sidewall 222a that contacts the first through electrode structure 120a.

In some embodiments, the first insulating sidewall 222a and the first through electrode structure 120a have the first combining structure S1, and the second insulating sidewall 222b and the second through electrode structure 120b also have the first combining structure S1. For example, the second insulating sidewall 222b partially extends into the second through electrode structure 120b. For example, the second insulating sidewall 222b penetrates a second plug barrier layer 124b of the second through electrode structure 120b and contacts a second conductive plug 122b. Accordingly, the second insulating sidewall 222b is partially surrounded by the second plug barrier layer 124b and a second insulating liner 110b that surrounds the second through electrode structure 120b.

In FIG. 2B, in an embodiment, the combining structure of the first through electrode structure 120a and the first insulating sidewall 222a and the combining structure of the second through electrode structure 120b and the second insulating sidewall 222b have the same first combining structure S1, but embodiments are not necessarily limited thereto, and in an embodiment, both combining structures have the second combining structure S2.

In some embodiments, the first insulating sidewall 222a and the first through electrode structure 120a have the second combining structure S2, and the second insulating sidewall 222b and the second through electrode structure 120b also have the second combining structure S2. For example, the first insulating sidewall 222a penetrates the first insulating liner 110a but does not penetrate the first plug barrier layer 124a. For example, the first insulating sidewall 222a contacts the first plug barrier layer 124a and is partially surrounded by a first insulating liner 110a.

FIG. 2C is an enlarged cross-sectional view of the region “I” in FIG. 1A of a semiconductor chip 10c according to some embodiments. For example, FIG. 2C is an enlarged view of the region “I” in FIG. 1A. FIG. 2C is the same as FIG. 2B, except that a distance between the first through electrode structure 120a and the second surface 109 of the semiconductor substrate 100 is the same as a distance between the second through electrode structure 120b and the second surface 109 of the semiconductor substrate 100.

Referring to FIG. 2C, in an embodiment, a length n a vertical (Z) direction of a first pillar portion 148a that contacts the first through electrode structure 120a i and a length n a vertical (Z) direction of a second pillar portion 148b that contacts the second through electrode structure 120b are equal to each other.

In some embodiments, the combining structure of the first through electrode structure 120a and the first insulating sidewall 222a and the combining structure of the second through electrode structure 120b and the second insulating sidewall 222b have the first combining structure S1. For example, the through electrode structures 120 that have the same distance from the second surface 109 of the semiconductor substrate 100 have the same combining structure with the insulating sidewall 222.

In FIG. 2C, in an embodiment, each of the through electrode structures 120 that has the same distance from the second surface 109 of the semiconductor substrate 100 have the first combining structure S1 and are combined with the insulating sidewall 222, but embodiments are not necessarily limited thereto, and in an embodiment, each of the through electrode structures 120 has the second combining structure S2.

In some embodiments, the through electrode structures 120 that have the same distance from the second surface 109 of the semiconductor substrate 100 have different combining structures. For example, the first through electrode structure 120a and the first insulating sidewall 222a have the second combining structure S2, and the second through electrode structure 120b and the second insulating sidewall 222b have the first combining structure S1.

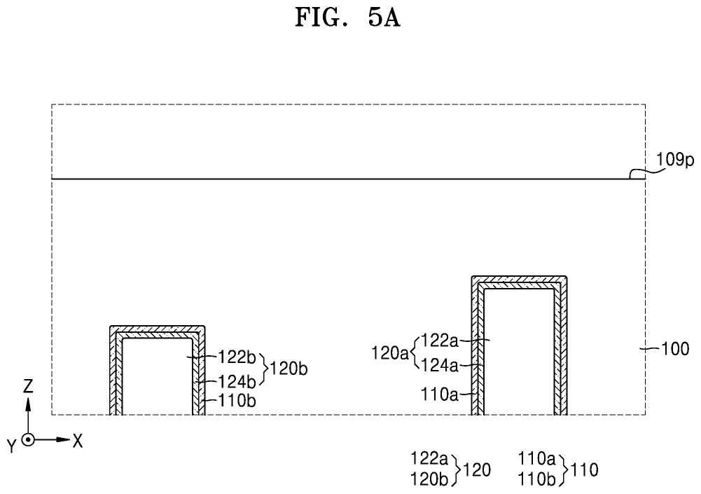

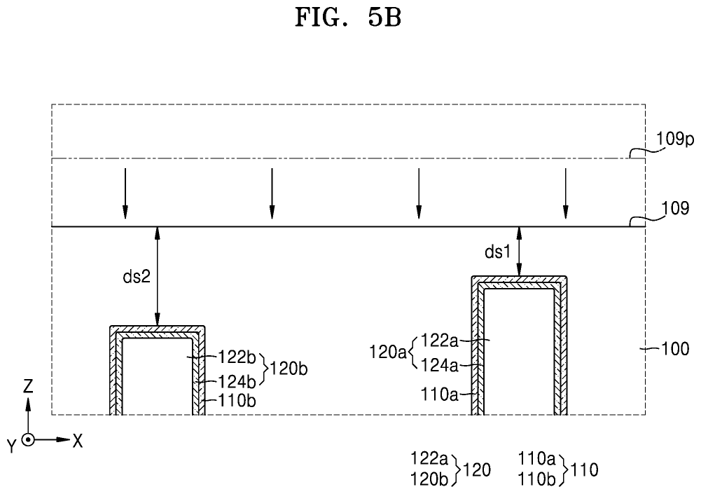

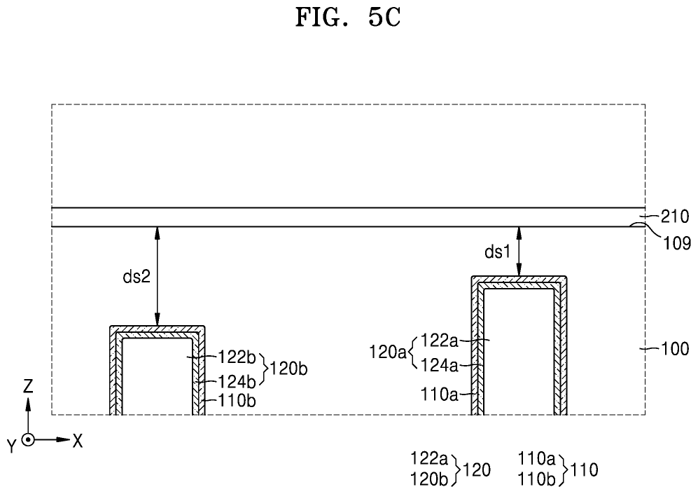

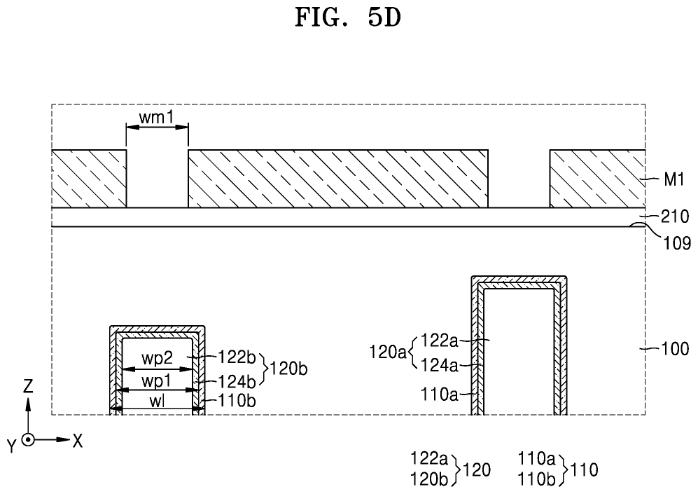

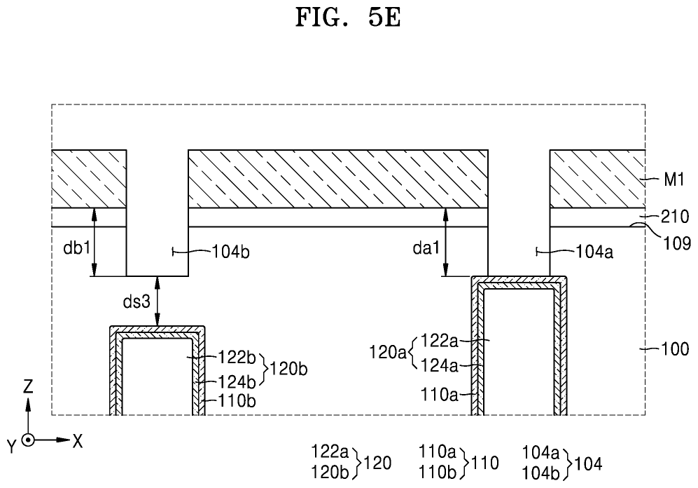

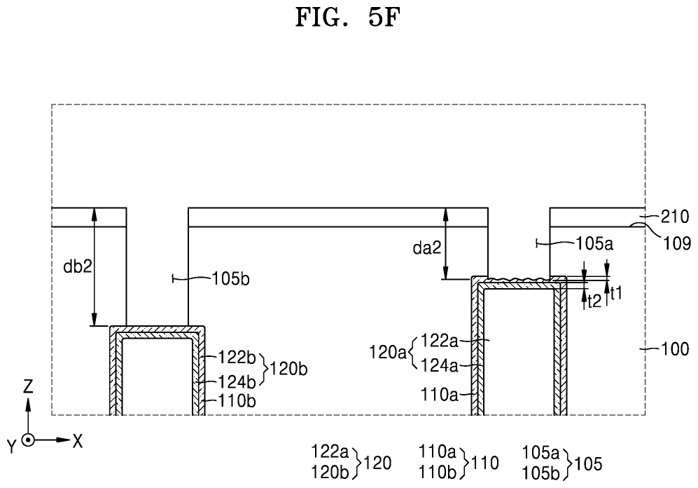

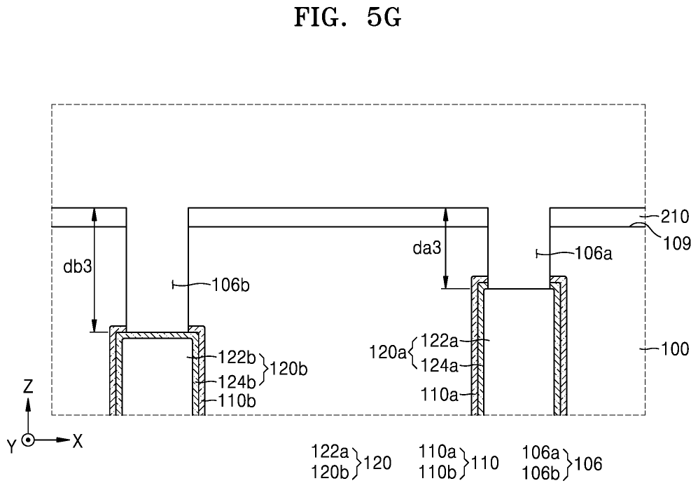

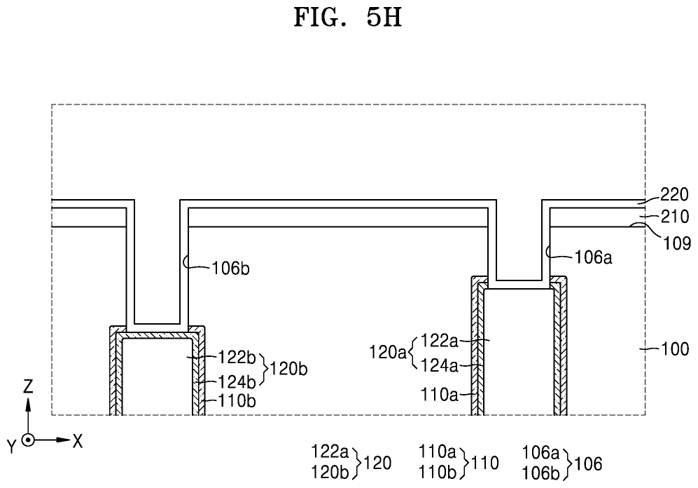

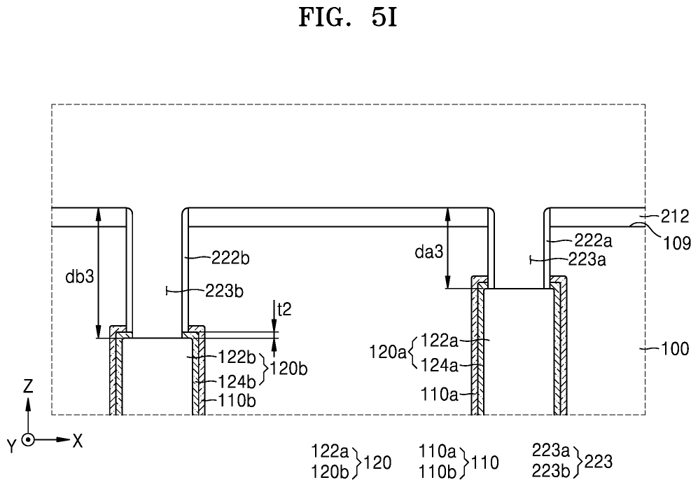

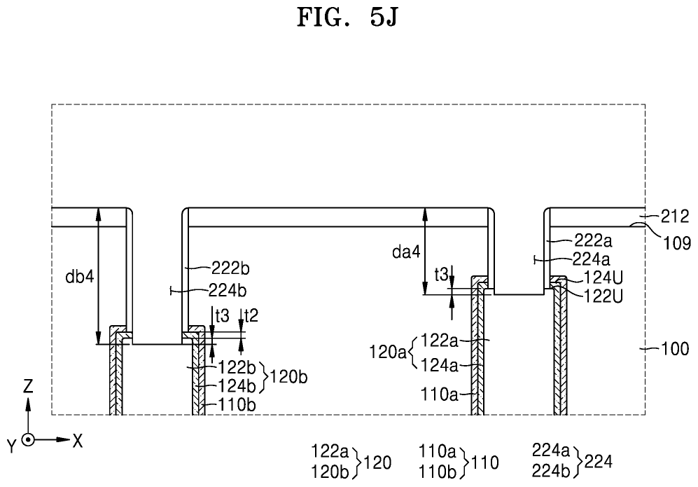

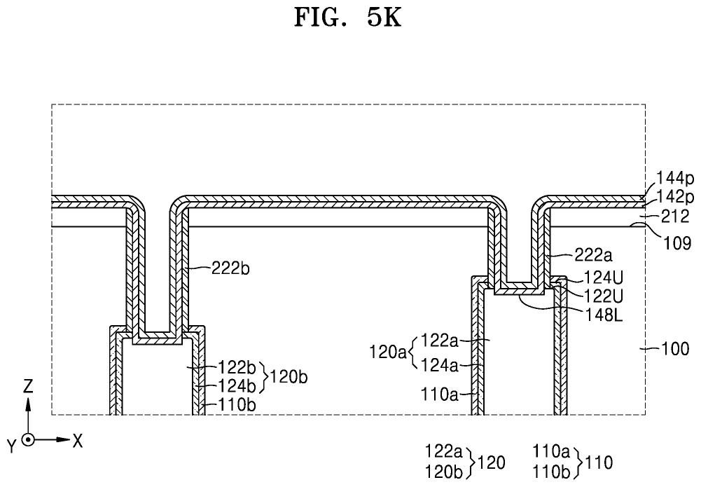

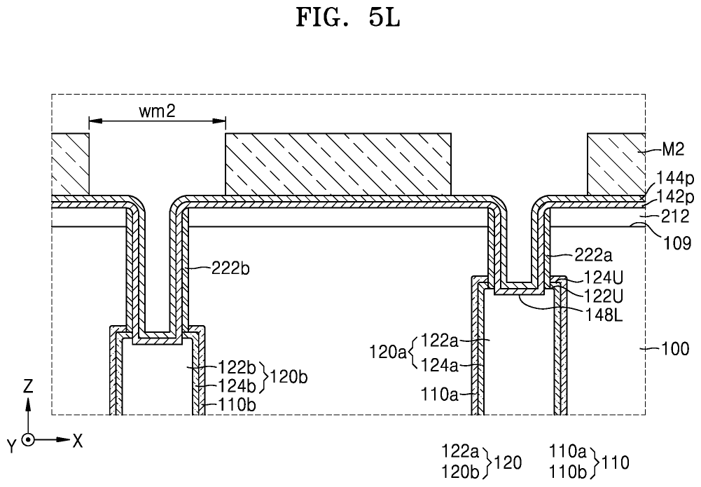

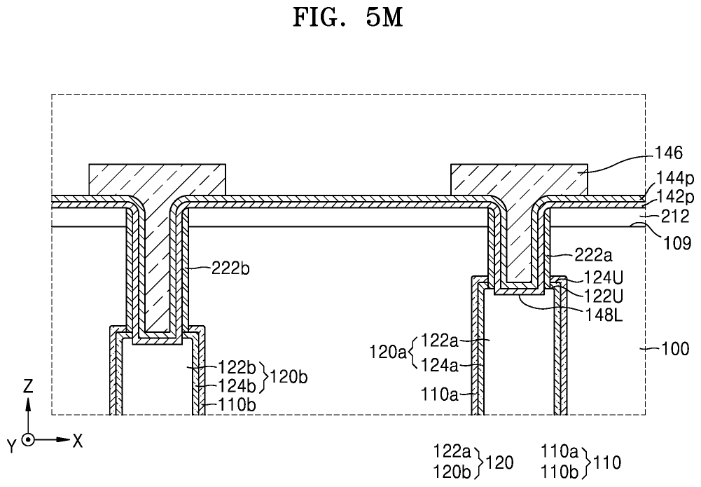

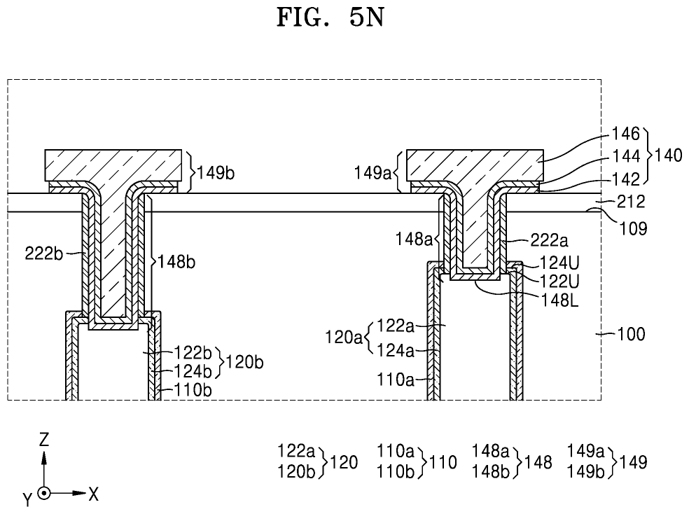

FIGS. 5A to 5N are cross-sectional views that illustrate a method of manufacturing the semiconductor chip 10, according to some embodiments. Hereinafter, a method of manufacturing the semiconductor chip 10 illustrated in FIGS. 1A, 2A, 3, 4A, and 4B is described with reference to FIGS. 5A to 5N.

Referring to FIG. 5A, in an embodiment, the semiconductor substrate 100, which includes the plurality of through electrode structures 120 therein and the first surface 107 and a preliminary second surface 109p opposite to each other, is prepared. In some embodiments, each of the plurality of through electrode structures 120 is surrounded by the insulating liner 110. In some embodiments, the through electrode structure 120 includes the conductive plug 122 and the plug barrier layer 124 that surrounds the conductive plug 122. For example, preparing the semiconductor substrate 100 is performed after forming the first semiconductor device layer 300 on the first surface 107 of the semiconductor substrate 100 and the first wiring structure 400 on the lower surface 307 of the semiconductor device layer 300.

Referring to FIG. 5B, in an embodiment, the second surface 109 is formed by partially removing the semiconductor substrate 100 from the preliminary second surface 109p. For example, the thickness in the vertical (Z) direction of the semiconductor substrate 100 is reduced through a grinding process or a polishing process performed on the preliminary second surface 109p.

In some embodiments, distances of the plurality of through electrode structures 120 from the second surface 109 of the semiconductor substrate 100 differ from each other. For example, a first depth ds1 between the first through electrode structure 120a and the second surface 109 of the semiconductor substrate 100 is less than a second depth ds2 between the second through electrode structure 120b and the second surface 109 of the semiconductor substrate 100.

Referring to FIG. 5C, in an embodiment, the first insulating layer 210 is formed on the second surface 109 of the semiconductor substrate 100.

Referring to FIG. 5D, in an embodiment, a first mask pattern M1 is disposed on the first insulating layer 210. The first mask pattern M1 includes a hole having a first width wm1 for forming the open hole 106. For example, the first width wm1 is substantially equal to the width of the open hole 106. For example, the first width wm1 is narrower than the width w1 in the horizontal direction of the insulating liner 110. For example, the first width wm1 is narrower than the width wp1 in the horizontal direction of the plug barrier layer 124. For example, the first width wm1 is narrower than the width wp2 in the horizontal direction of the conductive plug 122 or is substantially equal to the width wp2 in the horizontal direction of the conductive plug 122.

Referring to FIG. 5E, in an embodiment, the first insulating layer 210 and the semiconductor substrate 100 are partially removed. In some embodiments, a first preliminary open hole 104 is formed by penetrating the first insulating layer 210 and partially penetrating the semiconductor substrate 100. In some embodiments, at least some of the insulating liners 110 that surround the plurality of through electrode structures 120 are exposed through the first preliminary open hole 104.

In some embodiments, the first preliminary open hole 104 includes a first hole 104a formed in the first through electrode structure 120a and a second hole 104b formed in the second through electrode structure 120b. In some embodiments, the first insulating liner 110a that surrounds the first through electrode structure 120a is partially exposed by the first hole 104a. In some embodiments, the second insulating liner 110b that surrounds the second through electrode structure 120b is spaced apart in the vertical (Z) direction by a third depth ds3 from the second hole 104b disposed in the semiconductor substrate 100. For example, a first depth da1 of the first hole 104a in the vertical direction and a second depth db1 of the second hole 104b in the vertical direction are equal to each other.

In some embodiments, the first insulating layer 210 and the semiconductor substrate 100 are formed through a plasma etching process. For example, in the etching process, a fluorine-containing gas that includes at least one of SF₆, C₄F₈, or CF₄, etc., is used as a process gas. Materials scattered in the etching process can be identified through an optical emission spectrometer. For example, the first hole 104a is formed, and therefore, the first insulating liner 110a that surrounds the first through electrode structure 120a is partially exposed, and the material of the first insulating liner 110a can be observed through the optical emission spectrometer. For example, a time at which at least some of the insulating liners 110 that surround the through electrode structures 120 are exposed by forming the first preliminary open hole 104 can be identified through the optical emission spectrometer.

Referring to FIG. 5F, in an embodiment, an over-etch process is performed that additionally removes the semiconductor substrate 100 disposed between the second insulating liner 110b that surrounds the second through electrode structure 120b and the second hole 104b shown in FIG. 5E. For example, the second insulating liner 110b that surrounds the second through electrode structure 120b is partially exposed.

In some embodiments, a second preliminary open hole 105 is formed that partially exposes the insulating liner 110. In some embodiments, the second preliminary open hole 105 includes a third hole 105a that partially exposes the first insulating liner 110a and a fourth hole 105b that partially exposes the second insulating liner 110b. For example, when forming the second preliminary open hole 105, a signal that represents the material of the insulating liner 110 is received by the optical emission spectrometer.

In some embodiments, in the over-etch process described above, a part of the first insulating liner 110a that defines the third hole 105a is at least partially removed. For example, a part of the first insulating liner 110a exposed through the third hole 105a is thinner than a first thickness t1 of the remaining part of the first insulating liner 110a.

In some embodiments, the third hole 105a is limited by the first insulating layer 210, the semiconductor substrate 100, and the partially etched first insulating liner 110a. In some embodiments, the fourth hole 105b is limited by the first insulating layer 210, the semiconductor substrate 100, and the second insulating liner 110b. A third depth da2 in the vertical direction of the third hole 105a is less than a fourth depth db2 in the vertical direction of the fourth hole 105b.

Although the first through electrode structure 120a is not exposed in FIG. 5F, the first through electrode structure 120a is partially exposed in the over-etch process according to the thickness of the insulating liner 110 and the third depth ds3.

Referring to FIG. 5G, in an embodiment, the insulating liner 110 that surrounds the through electrode structure 120 is partially removed, and the open hole 106 is formed that partially exposes the through electrode structure 120. For example, the open hole 106 penetrates the insulating liner 110. In some embodiments, the open hole 106 include a fifth hole 106a that partially exposes the first through electrode structure 120a and a sixth hole 106b that partially exposes the second through electrode structure 120b.

In some embodiments, the fifth hole 106a partially penetrates the first through electrode structure 120a. For example, the fifth hole 106a penetrates the first plug barrier layer 124a and partially exposes the first conductive plug 122a. For example, the fifth hole 106a is limited by the first insulating layer 210, the semiconductor substrate 100, the first insulating liner 110a, the first plug barrier layer 124a, and the first conductive plug 122a.

In some embodiments, the sixth hole 106b does not penetrate the second through electrode structure 120b. For example, the sixth hole 106b partially exposes the second plug barrier layer 124b. For example, the sixth hole 106b is limited by the first insulating layer 210, the semiconductor substrate 100, the second insulating liner 110b, and the second plug barrier layer 124b.

In some embodiments, the sixth hole 106b partially penetrates the second through electrode structure 120b. For example, the sixth hole 106b penetrates the second plug barrier layer 124b and partially exposes the second conductive plug 122b. For example, the sixth hole 106b is limited by the first insulating layer 210, the semiconductor substrate 100, the second insulating liner 110b, the second plug barrier layer 124b, and the second conductive plug 122b. For example, the sixth hole 106b has substantially the same structure as the fifth hole 106a, and the semiconductor chip 10b according to FIG. 2B is manufactured through a subsequent process.

Referring to FIG. 5H, in an embodiment, the second insulating layer 220 is formed that conformally covers the upper surface of the first insulating layer 210, and a sidewall and a lower surface of the open hole 106.

Referring to FIGS. 5H and 5I together, in an embodiment, the pad insulating layer 212 and the insulating sidewall 222 are formed by partially removing the first insulating layer 210 and the second insulating layer 220. In some embodiments, a preliminary pad hole 223 that partially exposes the conductive plug 122 is formed by partially removing the second insulating layer 220 that covers the lower surface of the open hole 106. In some embodiments, when partially removing the second insulating layer 220, the second plug barrier layer 124b of the second through electrode structure 120b is partially removed.

In some embodiments, the preliminary pad hole 223 includes a first preliminary pad hole 223a that partially exposes the first conductive plug 122a of the first through electrode structure 120a and a second preliminary pad hole 223b that partially exposes the second conductive plug 122b of the second through electrode structure 120b.

In some embodiments, a fifth depth da3 in the vertical direction of the first preliminary pad hole 223a is the same as a length in the vertical direction of the first insulating sidewall 222a.

For example, the second preliminary pad hole 223b penetrates the second plug barrier layer 124b. For example, a sixth depth db3 in the vertical direction of the second preliminary pad hole 223b is greater than a length in the vertical direction of the second insulating sidewall 222b by a second thickness t2 of the second plug barrier layer 124b.

In some embodiments, the first preliminary pad hole 223a is limited by the first insulating sidewall 222a and the first conductive plug 122a.

In some embodiments, the second preliminary pad hole 223b is limited by the second insulating sidewall 222b, the second plug barrier layer 124b, and the second conductive plug 122b.

Referring to FIG. 5J, in an embodiment, the pad hole 224 is formed by partially removing the conductive plug 122 exposed through the preliminary pad hole 223. When forming the insulating sidewall 222 described above, impurities that include hydrogen fluoride (HF) and/or copper fluoride (CuF₂) may form in the exposed conductive plug 122. The impurities increase the contact resistance between the conductive plug 122 and the bonding pad structure 140. For example, the first conductive plug 122a is exposed before the second conductive plug 122b, and impurities form on the first conductive plug 122a in the process of exposing the second conductive plug 122b. Accordingly, the contact resistance between the through electrode structures 120, which have different distances from the second surface 109 of the semiconductor substrate 100, is not uniform.

In some embodiments, the upper surface of the conductive plug 122 exposed through the preliminary pad hole 223 and that includes the impurities is additionally partially removed. For example, the conductive plug 122 has a concave shape recessed inward from the upper surface 122U of the conductive plug 122 by a third thickness t3 of the additionally removed conductive plug 122. Accordingly, the electrical reliability of the semiconductor chip 10 is increased.

In some embodiments, the pad hole 224 includes a first pad hole 224a that partially penetrates the first conductive plug 122a and a second pad hole 224b that partially penetrates the second conductive plug 122b.

In some embodiments, a seventh depth da4 in the vertical direction of the first pad hole 224a is greater than a length in the vertical direction of the first insulating sidewall 222a by the third thickness t3. In some embodiments, an eighth depth db4 in the vertical direction of the second pad hole 224b is greater than a length in the vertical direction of the second insulating sidewall 222b by a thickness that is the sum of the second thickness t2 and the third thickness t3.

Referring to FIG. 5K, in an embodiment, a preliminary pad barrier layer 142p and a preliminary pad seed layer 144p are sequentially disposed on the entire pad insulating layer 212. For example, the preliminary pad barrier layer 142p and the preliminary pad seed layer 144p are disposed in the entire pad hole 224. For example, the preliminary pad barrier layer 142p and the preliminary pad seed layer 144p partially fill the pad hole 224.

Referring to FIGS. 5L and 5M, in an embodiment, a second mask pattern M2 is disposed on the preliminary pad seed layer 144p. The second mask pattern M2 includes a hole that has a second width wm2 in the horizontal direction that is substantially the same as the width in the horizontal direction of the pad portion 149 of the bonding pad structure 140. For example, the hole having the second width wm2 is formed over the pad hole 224.

In some embodiments, the conductive pad pattern 146 is formed on the preliminary pad seed layer 144p. In some embodiments, the conductive pad pattern 146 fills a space in the pad hole 224 where the preliminary pad barrier layer 142p and the preliminary pad seed layer 144p are not formed. In some embodiments, the conductive pad pattern 146 is formed on the pad insulating layer 212. For example, the conductive pad pattern 146 partially and vertically overlaps the pad insulating layer 212. After the conductive pad pattern 146 is formed, the second mask pattern M2 is removed.

Referring to FIGS. 5M and 5N together, in an embodiment, the pad barrier layer 142 and the pad seed layer 144 are formed by removing those parts of the preliminary pad barrier layer 142p and the preliminary pad seed layer 144p that do not vertically overlap the conductive pad pattern 146. In some embodiments, the process of partially removing the preliminary pad barrier layer 142p and the preliminary pad seed layer 144p includes an etching process. In some embodiments, parts of the preliminary pad barrier layer 142p and the preliminary pad seed layer 144p that vertically overlap the conductive pad pattern 146 are partially removed due to the isotropy of the etching process. For example, an outer surface of the pad portion 149 of the bonding pad structure 140 has an under-cut shape in which the pad barrier layer 142 and the pad seed layer 144 are recessed inward below the pad portion 149.

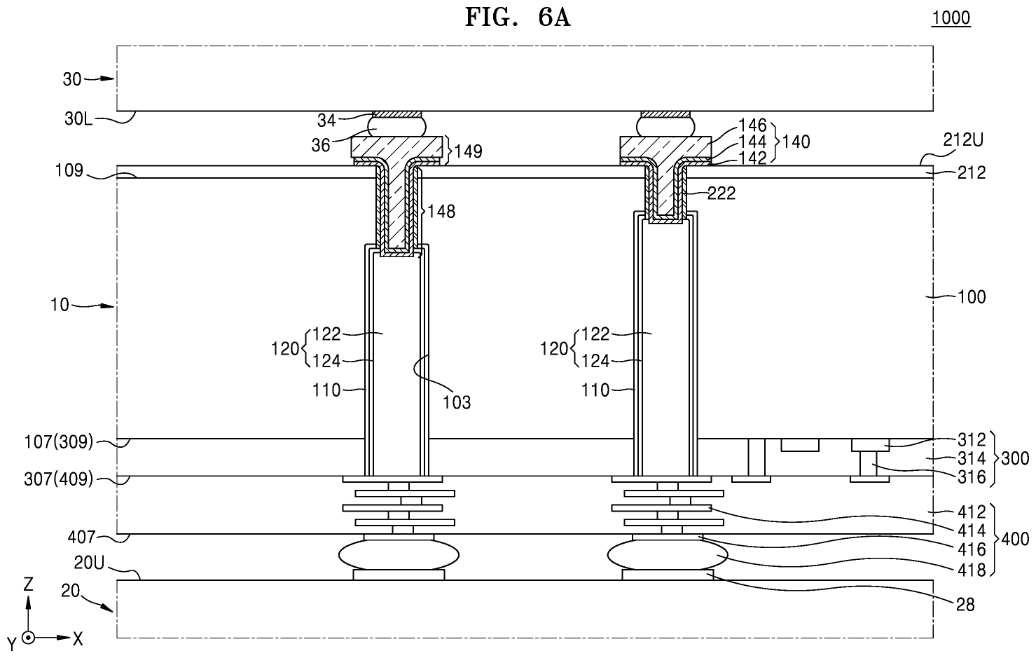

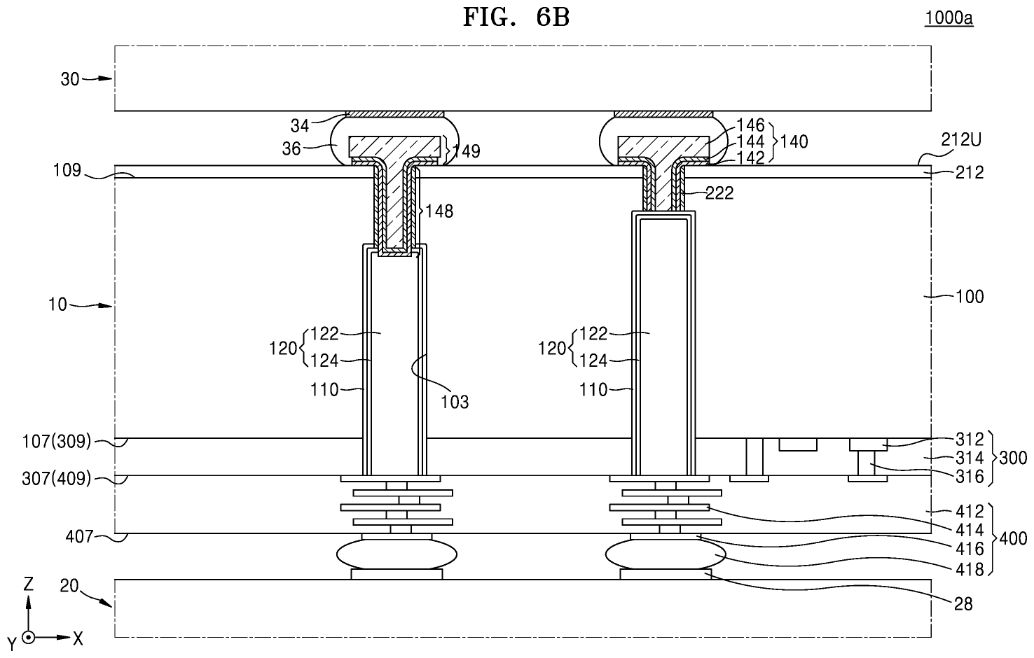

Hereinafter, semiconductor packages 1000 and 1000a that includes the semiconductor chip 10 according to some embodiments are described. Referring to FIGS. 6A and 6B, the semiconductor chip 10 and an upper structure 30 may be referred to as a first semiconductor chip and a second semiconductor chip, respectively.

FIG. 6A is a cross-sectional view of the semiconductor package 1000 according to some embodiments.

Referring to FIG. 6A, in an embodiment, the semiconductor package 1000 includes the semiconductor chip 10, a lower structure 20, and the upper structure 30. In some embodiments, the semiconductor chip 10 is disposed on the lower structure 20, and the upper structure 30 is disposed on the semiconductor chip 10.

In some embodiments, the upper structure 30 includes an upper pad 34 disposed on a lower surface 30L of the upper structure 30. In some embodiments, the upper pad 34 is electrically connected to the bonding pad structure 140 through an upper connection terminal 36. For example, the semiconductor chip 10 is electrically connected to the upper structure 30 through the upper connection terminal 36. In some embodiments, the upper connection terminal 36 is a solder ball or a solder bump.

Although FIG. 6A shows that the upper connection terminal 36 is in direct contact with the bonding pad structure 140, embodiments are not necessarily limited thereto, and in some embodiments, the semiconductor chip 10 further includes a wiring structure formed on the second surface 109 of the semiconductor substrate 100, as shown in FIG. 1B. For example, the upper connection terminal 36 is electrically connected to the bonding pad structure 140 through a wiring pattern of the wiring structure.

Although FIG. 6A shows that the semiconductor chip 10 and the upper structure 30 are bonded to each other through the upper connection terminal 36, embodiments are not necessarily limited thereto, and in some embodiments, the semiconductor chip 10 and the upper structure 30 are bonded to each other by direct bonding or hybrid bonding.

In some embodiments, the bonding pad structure 140 of the semiconductor chip 10 is directly bonded to the upper pad 34 of the upper structure 30. For example, the upper pad 34 and the bonding pad structure 140 are vertically aligned in a line, and are bonded to each other by thermos-compression. In some embodiments, the semiconductor chip 10 includes a first upper insulating layer that exposes an upper surface of the bonding pad structure 140 and surrounds the bonding pad structure 140, and the upper structure 30 includes a first lower insulating layer that exposes and surrounds the upper pad 34. The first upper insulating layer and the first lower insulating layer are bonded to each other in contact with each other.

In some embodiments, when the semiconductor chip 10 further includes a wiring structure formed on the second surface 109 of the semiconductor substrate 100, a contact pad formed on an upper surface of the wiring structure is directly bonded to the upper pad 34.

In some embodiments, the semiconductor chip 10 further includes a lower connection terminal 418 formed on the first contact pad 416. In some embodiments, the lower structure 20 includes a lower pad 28 formed on an upper surface 20U of the lower structure 20, and the lower pad 28 is electrically connected to the first contact pad 416 through the lower connection terminal 418. For example, the semiconductor chip 10 is bonded to the lower structure 20 through the lower connection terminal 418, and the semiconductor chip 10 and the lower structure 20 are electrically connected to each other.

Although FIG. 6A illustrates that the semiconductor chip 10 and the lower structure 20 are bonded to each other through the lower connection terminal 418, embodiments are not necessarily limited thereto, and in some embodiments, the semiconductor chip 10 and the lower structure 20 are bonded to each other by direct bonding or hybrid bonding without the lower connection terminal 418. In some embodiments, the first contact pad 416 is directly bonded to the lower pad 28 of the lower structure 20. For example, the first contact pad 416 and the lower pad 28 are vertically aligned in a line, and are bonded to each other by thermos-compression.

In some embodiments, the upper structure 30 is a core chip that includes DRAM memory cells. In some embodiments, the semiconductor chip 10 is one of a central processing unit (CPU) chip, a graphic processing unit (GPU) chip, or an application processor (AP) chip. In some embodiments, the semiconductor chip 10 is a buffer chip that controls the upper structure 30. In some embodiments, the lower structure 20 is an interposer. For example, the lower structure 20 is one of a S1 interposer or a re-distribution layer (RDL) interposer. In some embodiments, the upper structure 30 is a main board. For example, the upper structure 30 is a printed circuit board. For example, the upper structure 30 is a multi-layer printed circuit board.

In some embodiments, the upper structure 30 and the semiconductor chip 10 are core chips that include DRAM memory cells. In some embodiments, the lower structure 20 is a core chip. For example, the semiconductor package 1000 is a stack of a plurality of core chips. In some embodiments, the lower structure 20 is a buffer chip.

Although FIG. 6A illustrates that the semiconductor package 1000 includes one lower structure 20, embodiments are not necessarily limited thereto, and in some embodiments, the semiconductor package 1000 includes a plurality of lower structures 20. For example, the plurality of lower structures 20 are sequentially stacked below the semiconductor chip 10. In some embodiments, the semiconductor package 1000 is a high bandwidth memory (HBM) chip.

FIG. 6B is a cross-sectional view of a semiconductor package 1000a according to some embodiments. A difference between FIGS. 6A and 6B is whether the upper connection terminals 36 surround an under-cut structure of the pad portion 149 of the bonding pad structure 140.

Referring to FIG. 6B, in an embodiment, the width in the horizontal direction of the upper connection terminal 36 is greater than the width in the horizontal direction of the pad portion 149 of the bonding pad structure 140.

In some embodiments, the upper connection terminal 36 melts by heating, and contacts the bonding pad structure 140 in a molten state. In some embodiments, the molten upper connection terminal 36 surrounds an upper surface and an outer surface of the pad portion 149 of the bonding pad structure 140, and surrounds a lower under-cut of the outer surface of the pad portion 149. Thereafter, the molten upper connection terminal 36 solidifies through cooling, and a structure is formed that surrounds the under-cut of the pad portion 149.

While embodiments of the inventive concept has been particularly shown and described with reference to the drawings, it will be understood that various changes in form and details may be made therein without departing from the spirit and scope of the following claims.

What is claimed is:

1. A semiconductor chip, comprising:
a semiconductor substrate;
a pad insulating layer disposed on the semiconductor substrate;
a through electrode structure that partially penetrates the semiconductor substrate but does not penetrate the pad insulating layer;
an insulating liner that at least partially surrounds the through electrode structure;
an insulating sidewall that penetrates the pad insulating layer, a part of the semiconductor substrate and at least a part of the insulating liner, and includes a pad hole formed therein; and
a bonding pad structure disposed on the pad insulating layer and that fills the pad hole and contacts the through electrode structure.

2. The semiconductor chip of claim 1, wherein the insulating sidewall contacts the through electrode structure.

3. The semiconductor chip of claim 1, wherein a width in a horizontal direction of the insulating sidewall is narrower than a width in the horizontal direction of the insulating liner.

4. The semiconductor chip of claim 1, wherein a width in a horizontal direction of the pad hole is narrower than a width in the horizontal direction of the through electrode structure.

5. The semiconductor chip of claim 1, wherein the bonding pad structure partially penetrates the through electrode structure and is partially surrounded by the through electrode structure and the insulating liner.

6. The semiconductor chip of claim 1, wherein the through electrode structure includes
a conductive plug; and
a plug barrier layer that at least partially surrounds the conductive plug.

7. The semiconductor chip of claim 6, wherein the bonding pad structure partially penetrates the conductive plug.

8. The semiconductor chip of claim 6, wherein the insulating sidewall contacts the plug barrier layer, and
does not contact the conductive plug.

9. The semiconductor chip of claim 6, wherein the insulating sidewall penetrates the plug barrier layer,
is partially surrounded by the plug barrier layer, and
contacts the conductive plug.

10. The semiconductor chip of claim 1, wherein the bonding pad structure includes
a pillar portion disposed in a pad hole; and
a pad portion disposed on the pad insulating layer, wherein
a side surface of the pad portion has an under-cut structure in which a lower portion thereof is recessed inward.

11. A semiconductor chip, comprising:
a semiconductor substrate that includes a first surface and a second surface opposite to each other;
a pad insulating layer disposed on the second surface of the semiconductor substrate;
a through electrode structure that partially penetrates the semiconductor substrate but does not penetrate the pad insulating layer, wherein the through electrode structure includes a conductive plug and a plug barrier layer that surrounds the conductive plug;
an insulating liner that at least partially surrounds the through electrode structure;
an insulating sidewall that penetrates the semiconductor substrate, the pad insulating layer and the insulating liner, and includes a pad hole formed therein; and
a bonding pad structure disposed in the pad hole and that partially and vertically overlaps the pad insulating layer and partially penetrates the through electrode structure,
wherein the through electrode structure includes a first through electrode structure and a second through electrode structure, and
an upper surface of the first through electrode structure is vertically closer to the second surface of the semiconductor substrate than an upper surface of the second through electrode structure.

12. The semiconductor chip of claim 11, wherein
the first through electrode structure is partially penetrated by the insulating sidewall, and
the insulating sidewall contacts the conductive plug and is partially covered by the plug barrier layer.

13. The semiconductor chip of claim 12, wherein
the second through electrode structure is partially penetrated by the insulating sidewall, and
the insulating sidewall contacts the conductive plug and is partially covered by the plug barrier layer.

14. The semiconductor chip of claim 11, wherein
the second through electrode structure is not penetrated by the insulating sidewall, and
the insulating sidewall contacts the plug barrier layer and is partially covered by the insulating liner.

15. The semiconductor chip of claim 12, wherein the bonding pad structure includes:
a first bonding pad structure that partially penetrates the first through electrode structure and a second bonding pad structure that partially penetrates the second through electrode structure, wherein
each of the first bonding pad structure and the second bonding pad structure includes a pillar portion disposed in a pad hole, and a pad portion disposed on the pad insulating layer and integrally formed with the pillar portion, and
a length in a vertical direction of the pillar portion of the first bonding pad structure is less than a length in the vertical direction of the pillar portion of the second bonding pad structure.

16. A semiconductor package, comprising:
a first semiconductor chip; and
a second semiconductor chip disposed on the first semiconductor chip,
wherein the second semiconductor chip includes an upper pad disposed on a lower surface thereof and an upper connection terminal that contacts the upper pad,
wherein the first semiconductor chip comprises:
a wiring structure;
an interlayer insulating layer that surrounds the wiring structure;
a semiconductor substrate disposed on the interlayer insulating layer;
a pad insulating layer disposed on the semiconductor substrate;
a through electrode structure that partially penetrates the semiconductor substrate but does not penetrate the pad insulating layer;
an insulating liner that at least partially surrounds the through electrode structure;
an insulating sidewall that penetrates the pad insulating layer, a part of the semiconductor substrate and at least a part of the insulating liner, and includes a pad hole formed therein; and
a bonding pad structure that includes a pillar portion that fills the pad hole and a pad portion that covers a part of the pad insulating layer and contacts the through electrode structure, wherein
the first semiconductor chip is electrically connected to the second semiconductor chip through a contact between the bonding pad structure and the upper connection terminal.

17. The semiconductor package of claim 16, wherein
the pad portion of the bonding pad structure includes an under-cut structure in a lower portion thereof, and
the upper connection terminal surrounds at least a part of the under-cut structure.

18. The semiconductor package of claim 16, wherein a width in a horizontal direction of the insulating sidewall is narrower than a width in the horizontal direction of the through electrode structure.

19. The semiconductor package of claim 16, wherein the insulating sidewall partially penetrates the through electrode structure.

20. The semiconductor package of claim 19, wherein
the pillar portion partially penetrates the through electrode structure,
a thickness in a vertical direction of a part of the pillar portion that penetrates the through electrode structure is greater than a thickness in the vertical direction of a part of the insulating sidewall that penetrates the through electrode structure.
